(19) United States
(12) Patent Application Publication
(10) Pub. No.: US 2025/0180667 A1
(43) Pub. Date: Jun. 5, 2025

(54) RELIABILITY, AVAILABILITY, AND SAFETY IN A SYSTEM USING IN-CONNECTOR THERMAL MONITORING

(71) Applicant: INTERNATIONAL BUSINESS MACHINES CORPORATION, ARMONK, NY (US)

(72) Inventors: BRIAN CHARLES TUCKER, CLINTON CORNERS, NY (US); MARC HENRI COQ, HOPEWELL JUNCTION, NY (US); ENVER CANDAN, FISHKILL, NY (US)

(21) Appl. No.: 18/524,719

(22) Filed: Nov. 30, 2023

(51) Int. Cl. G01R 31/66

(52) U.S. Cl. CPC G01R 31/66

(57) ABSTRACT

In a particular embodiment, improving reliability, availability, and safety in a system using in-connector thermal monitoring includes identifying an expected installation of connections among devices in a system. Temperature data collected by one or more thermal sensors of one or more connectors in the system is received by a connection monitoring module. The connection monitoring module determines, based on the expected installation and the temperature data, whether a fault is present in one or more connections of the system.

### BACKGROUND

The present disclosure relates to methods, apparatus, and products for improving reliability, availability, and safety in a system using in-connector thermal monitoring. When equipment is purchased, moved, or reassembled, the power connections for the equipment are installed by a technician ideally in accordance with an installation specification or expected configuration. However, such installations are susceptible to human error. Further, improper power connections or improper installations of power connections, as well as failing connectors, can lead to unreliability, poor performance, or even damage to equipment.

### SUMMARY

According to embodiments of the present disclosure, various methods, apparatus and products for improving reliability, availability, and safety in a system using in-connector thermal monitoring are described herein. In some aspects, improving reliability, availability, and safety in a system using in-connector thermal monitoring includes identifying an expected installation of connections among devices in a system or a distributed system. Temperature data collected by one or more thermal sensors of one or more connectors in the system is received by a connection monitoring module. The connection monitoring module determines, based on the expected installation and the temperature data, whether a fault is present in one or more connections of the system.

### BRIEF DESCRIPTION OF THE DRAWINGS

FIG. 1 sets forth an example computing environment according to aspects of the present disclosure.

FIG. 2 sets forth an example connector for improving reliability, availability, and safety in a system using in-connector thermal monitoring in accordance with at least one embodiment of the present disclosure.

FIG. 3A sets forth a block diagram of an example power connection for improving reliability, availability, and safety in a system using in-connector thermal monitoring in accordance with at least one embodiment of the present disclosure.

FIG. 3B sets forth a block diagram of another example power connection for improving reliability, availability, and safety in a system using in-connector thermal monitoring in accordance with at least one embodiment of the present disclosure.

FIG. 3C sets forth a block diagram of another example power connection for improving reliability, availability, and safety in a system using in-connector thermal monitoring in accordance with at least one embodiment of the present disclosure.

FIG. 4 sets forth a block diagram of an example power system for improving reliability, availability, and safety in a system using in-connector thermal monitoring in accordance with at least one embodiment of the present disclosure.

FIG. 5 sets forth an example installation specification for improving reliability, availability, and safety in a system using in-connector thermal monitoring in accordance with at least one embodiment of the present disclosure.

FIG. 6 sets forth an example connection monitoring log for improving reliability, availability, and safety in a system using in-connector thermal monitoring in accordance with at least one embodiment of the present disclosure.

FIG. 7 sets forth an example connection monitoring log for improving reliability, availability, and safety in a system using in-connector thermal monitoring in accordance with at least one embodiment of the present disclosure.

FIG. 8 sets forth an example connection monitoring log for improving reliability, availability, and safety in a system using in-connector thermal monitoring in accordance with at least one embodiment of the present disclosure.

FIG. 9 sets forth a flow chart of a method for improving reliability, availability, and safety in a system using in-connector thermal monitoring in accordance with at least one embodiment of the present disclosure.

FIG. 10 sets forth a flow chart of a method for improving reliability, availability, and safety in a system using in-connector thermal monitoring in accordance with at least one embodiment of the present disclosure.

FIG. 11 sets forth a flow chart of a method for improving reliability, availability, and safety in a system using in-connector thermal monitoring in accordance with at least one embodiment of the present disclosure.

### DETAILED DESCRIPTION

Electronic equipment, such as information technology, communications, automation and control, industrial, or other equipment that operate in a high-availability mode requires a robust electrical power source. A common failure point in line-connected systems is the failure of an electrical contact within a plug or receptacle.

In systems utilizing redundant power supplies, there exists a risk that the equipment line cord may be connected to an incorrect receptacle and/or with an incorrect plug due to human error or other factors. An incorrect line cord connection reduces the overall availability of the equipment and may prolong any associated outage.

Equipment that utilizes common ‘appliance coupler’ style line cords, such as the International Electrotechnical Commission (IEC) C13, C14, C19, and C20 style connectors, are commonly available in a multitude of wire gauges, overall lengths, and build qualities. This wide variety of available cables increases the risk that a cable of insufficient ampacity, excessive length, or insufficient quality, might be used to connect equipment, thereby increasing the risk of failure or fire.

A failing mains connection may not be noticed quickly, leading to potential equipment outages, with the damaged components lengthening the service outage due to a need for immediate, unscheduled service. Additionally, a mains connection with too much resistive loss may result in excessive power consumption, unexpected protection device trips, smoke, or fire.

Embodiments in accordance with the present disclosure provide a mechanism of not only measuring a connector temperature but also determining if system power components have been cabled to the correct locations, and optionally with the correct gauge wire, by cross-referencing performance data with lookup tables of the expected system configuration.

Additionally, these mechanisms can issue warnings about an elevated temperature that may lead to a failure, with the ability to take action by opening circuits or otherwise reducing the load on an affected circuit. By measuring temperature of both plugs and/or receptacles and comparing them within defined thresholds, system characteristics, and averages of operating temperatures over time, embodiments can reduce false alerts and also provide alerts to slowly developing reliability issues.

Embodiments can determine if an equipment input power connection is failing, may have been connected with the incorrect line cord, or may be connected to the incorrect plugging location. In various embodiments, a thermal sensing device is built into either the receptacle or plug, or both. This sensor may be attached within facilities power distribution equipment, localized power distribution equipment, or the point of load itself. Additionally, this sensor may be situated within a line cord plug with sensor wires being routed in the line cord assembly. In some examples, an analog circuit with or without common microcontroller circuitry may be used to observe the temperature at the thermal sensor and either report a high temperature condition, open the offending circuit, and potentially provide means for reporting of said condition to an upstream microcontroller or locally visible device. These mechanisms can be standalone or incorporated as part of a finished product or system, allowing for continuous protection and monitoring of the connector system.

The features of embodiments for improving reliability, availability, and safety in a system using in-connector thermal monitoring can include thermal sensors that provide a ‘cable check’ by verifying that applied loads result in temperature elevations at the correct connector location, which are correlated with a pre-defined lookup table, as well as the ability to detect temperature of critical power connections via thermal sensor integration. The thermal sensors can be separate mechanical assembly or molded into connector bodies. Monitoring circuitry can be installed in facility equipment or integrated into products. Mechanisms are provided for detecting failing or problematic conditions, such as failing connector contacts, a partially installed connector, insufficient wire gauge, grossly excessive length, or excessive or abnormal load condition. The monitoring circuitry can reduce current in the event of a failure, actuate shunt trip circuit breakers, open relays, shut down equipment, or otherwise reduce load on the cable system, and redundant systems can automatically initiate a failover to a different power supply.

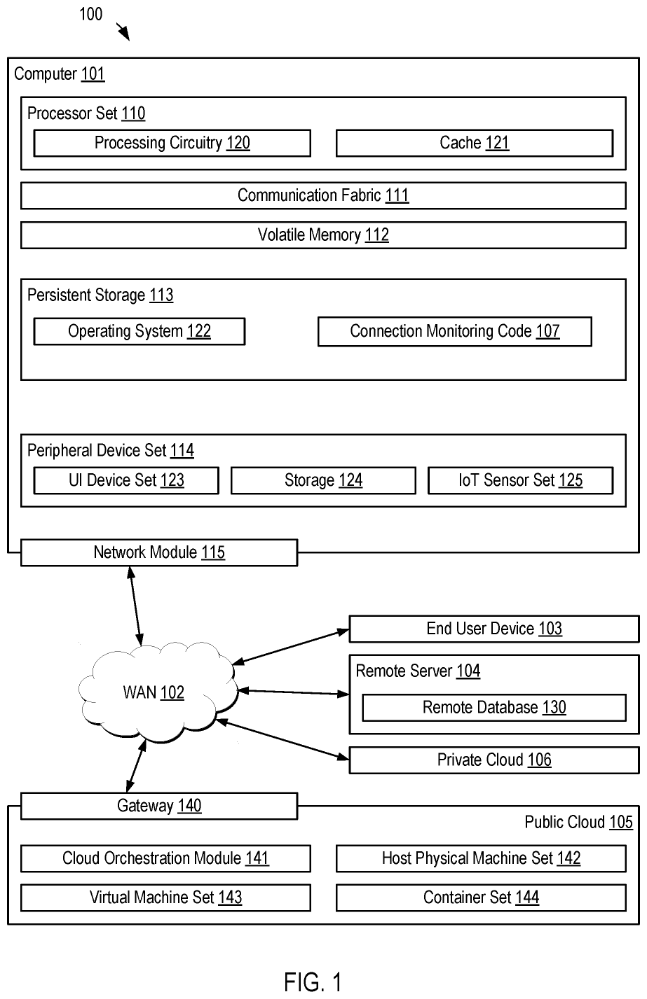

With reference now to FIG. 1, FIG. 1 sets forth an example computing environment according to aspects of the present disclosure. Computing environment 100 contains an example of an environment for the execution of at least some of the computer code involved in performing the various methods described herein, such as connection monitoring code 107. In some examples, connection monitoring code 107 includes processor-executable instructions for identifying an expected installation of power connections among devices in a system, receiving temperature data collected by one or more thermal sensors of one or more power connectors in the system, and determining, based on the expected installation and the temperature data, whether a fault is present in one or more power connections of the system.

In addition to block 107, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 107, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 121 and the other storage media discussed below. The program instructions, and associated data, are accessed by processor set 110 to control and direct performance of the computer-implemented methods. In computing environment 100, at least some of the instructions for performing the computer-implemented methods may be stored in block 107 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 107 typically includes at least some of the computer code involved in performing the computer-implemented methods described herein.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the computer-implemented methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

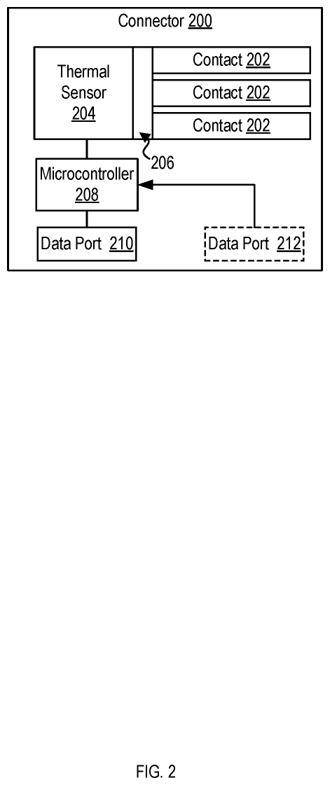

FIG. 2 sets forth a block diagram of an example connector for improving reliability, availability, and safety in a system using in-connector thermal monitoring in accordance with at least one embodiment of the present disclosure. In some examples, the connector 200 may be a receptacle connector such as an International Electrotechnical Commission (IEC) C13 or IEC C19 connector, although embodiments of the present disclosure are not limited to such receptacle connectors. In some examples, the connector 200 may be a plug connector such as an IEC C14 or IEC C20 connector although embodiments of the present disclosure are not limited to such plug connectors. The connector 200 may be a power receiving connector or a power supplying connector. For example, the connector 200 may be a plug or receptacle of a power receiving device, the connector 200 may be a plug or receptacle of a power supplying device, or the connector 200 may be a plug or receptacle of a power cable for conveying power from the power supplying device to the power receiving device. For power conveyance, the connector 200 includes two or more contacts 202. For example, the contacts 202 of a plug connector mate with the contacts 202 of a receptacle connector. Thus, the connector 200 may be any connector within a power supply and distribution system.

The connector 200 further includes one or more thermal sensors 204. In some examples, a thermal sensor 204 is coupled to the contacts 202 through a thermal interface 206. The thermal sensor 204 may be any thermal sensor capable of measuring ambient temperature. In some examples, there may be one thermal sensor 204 thermally coupled to all of the contacts 202, while in other examples there may be a thermal sensor 204 for each contact 202. In the example of FIG. 2, one thermal sensor 204 is provided. The thermal sensor 204 is communicatively coupled to a microcontroller 208. In some examples, as shown in FIG. 2, the microcontroller 208 is located within the connector 200. However, in other examples, the microcontroller 208 may be outside of the connector 200 such as a microcontroller coupled to the connector 200 or a microcontroller within a device to which the connector 200 is coupled (e.g., a microcontroller in a power receiving device or a power supplying device). The microcontroller 208 receives the temperature readings from the one or more thermal sensors 204. In some examples, the microcontroller 208 transmits temperature data through a data port 210 when the microcontroller 208 is located within or coupled to the connector 200. The data port 210 may be configured for communication with a connection monitoring module (not shown) or another mated connector (not shown). In some examples, the connector 200 includes another data port 212 that may be configured to receive temperature data from a mated connector, as will be described in more detail below.

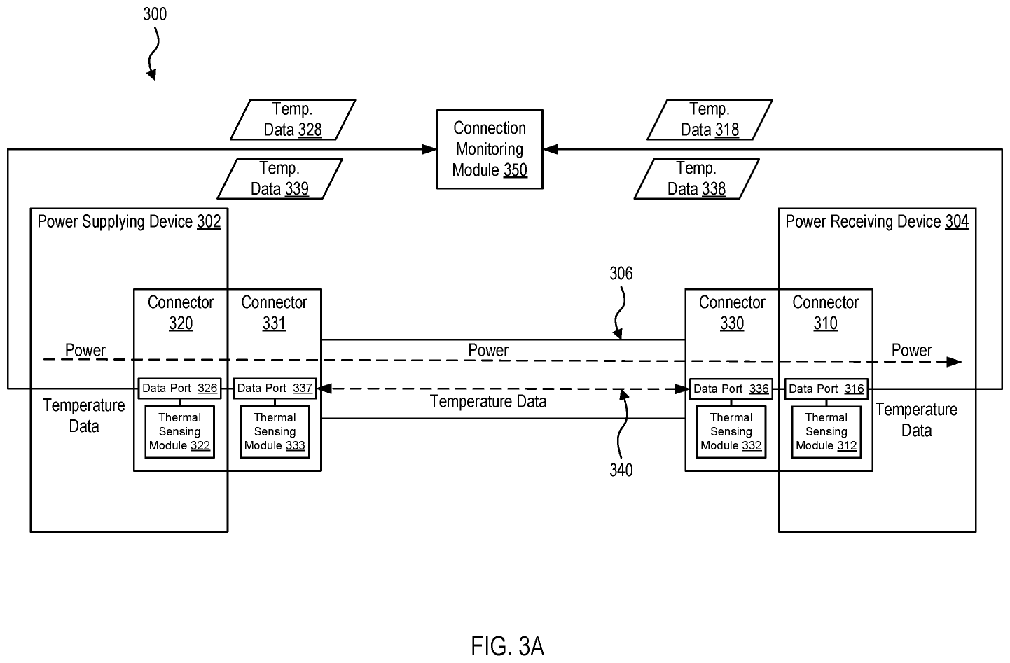

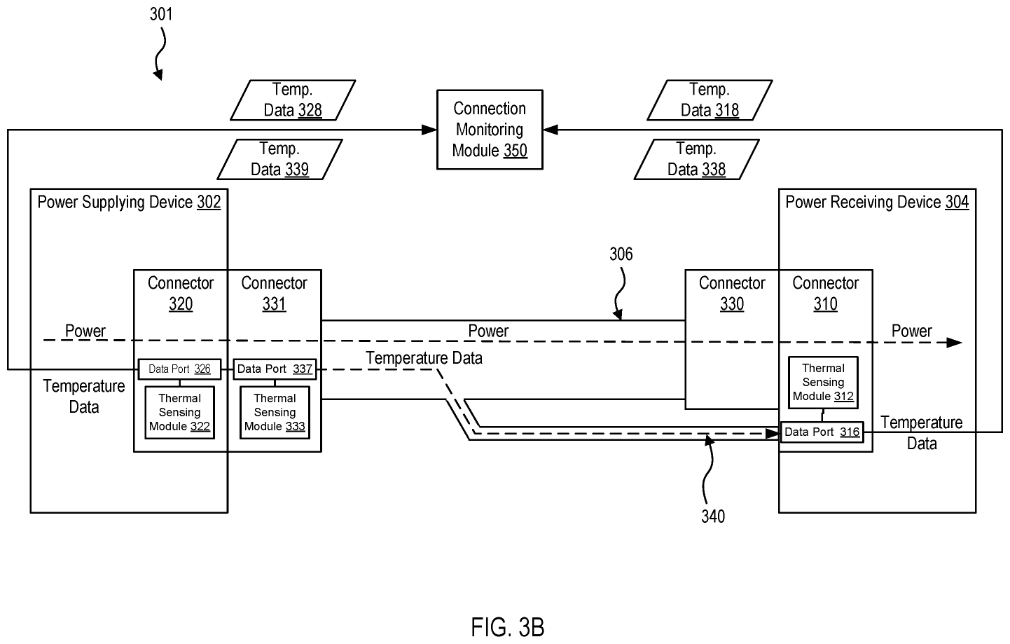

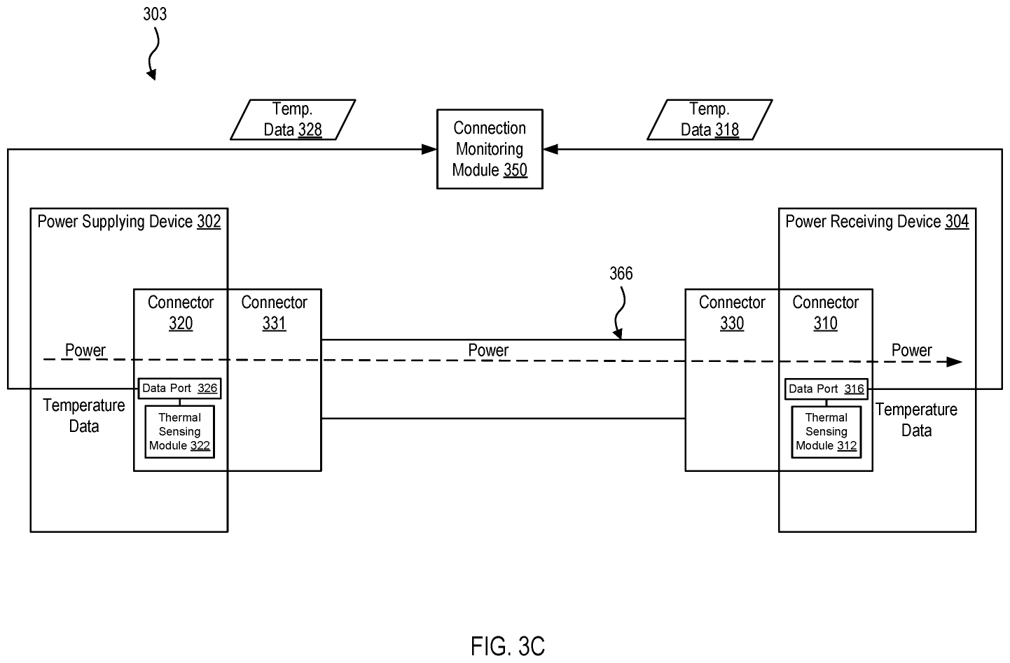

For further explanation, FIG. 3A sets forth a block diagram of an example power connection 300 for improving reliability, availability, and safety in a system using in-connector thermal monitoring in accordance with at least one embodiment of the present disclosure. The example of FIG. 3A includes a power connection between a power receiving device 302 and a power supplying device 304 through an enhanced power cable 306. For example, the power receiving device 302 may be a power supply unit and the power supplying device 304 may be a power distribution unit. In the example of FIG. 3A, the power receiving device 302 includes a connector 310 (e.g., a plug) that includes a thermal sensing module 312. For example, the thermal sensing module 312 includes the thermal sensor(s), microcontroller, and data port(s) discussed above with reference to FIG. 2. The thermal sensing module 312 is communicatively coupled to a connection monitoring module 350, which is described in more detail below. The thermal sensing module 312 is configured to transmit temperature data 318 collected by the thermal sensing module 312 in the power receiving device connector to the connection monitoring module 350.

In the example of FIG. 3A, the power supplying device 304 includes a connector 320 (e.g., a receptacle) that includes a thermal sensing module 322. For example, the thermal sensing module 322 includes the thermal sensor(s), microcontroller, and data port(s) discussed above with reference to FIG. 2. The thermal sensing module 322 is communicatively coupled to the connection monitoring module 350. The thermal sensing module 322 is configured to transmit temperature data 328 collected by the thermal sensing module 322 in the power supply unit connector to the connection monitoring module 350.

In the example of FIG. 3A, the enhanced power cable 306 includes a first connector 330 and a second connector 331 (e.g., a plug and a receptacle). Each connector 330, 331 includes a respective thermal sensing module 332, 333. For example, the thermal sensing modules 332, 333 include the thermal sensor(s), microcontroller, and data port(s) discussed above with reference to FIG. 2. The thermal sensing modules 332, 333 are configured to transmit temperature data 338, 339, which is then received by the connection monitoring module. In some implementations, a data port 336 of the thermal sensing module 332 interfaces with a data port 316 of the connector 310 in the power receiving device 302. In these implementations, the thermal sensing module 332 provides temperature data 338 collected in the connector 330 to the thermal sensing module 312 in the connector 310. The thermal sensing module 312 transmits temperature data 318 collected by the thermal sensing module 312 and temperature data 338 collected by the thermal sensing module 332 to the connection monitoring module 350. In other implementations, the thermal sensing module 332 may transmit the temperature data 338 wirelessly to the connection monitoring module.

Similarly, in some implementations, a data port 337 of the thermal sensing module 333 interfaces with a data port 326 of the connector 320 in the power supplying device 304. In these implementations, the thermal sensing module 333 provides temperature data 339 collected in the connector 331 to the thermal sensing module 322 in the connector 320. The thermal sensing module 322 transmits the temperature data 328 collected by the thermal sensing module 322 and temperature data 339 collected by the thermal sensing module 333 to the connection monitoring module 350. In other implementations, the thermal sensing module 333 may transmit the temperature data 339 wirelessly to the connection monitoring module.

In some implementations, the enhanced power cable 306 includes a data line 340. In these implementations, the data line 340 provides the sharing of temperature data between the connectors 330, 331. Thus, temperature data 338 collected in connector 330 may be provided by the thermal sensing module 332 to the thermal sensing module 333 in connector 331 through data line 340. Likewise, temperature data 339 collected in connector 331 may be provided by the thermal sensing module 333 to the thermal sensing module 332 in connector 330 through data line 340. In such implementations, the thermal sensing module 312 in the power receiving device connector 310 may report temperature data 318 from the power receiving device connector, temperature data 338 from the first power cable connector, and temperature data 339 from the second power cable connector. Likewise, the thermal sensing module 332 in the power supplying device connector 320 may report temperature data 328 from the power supplying device connector, temperature data 338 from the first power cable connector, and temperature data 339 from the second power cable connector. In an alternative implementation, either the power receiving device connector 310 or the power supplying device connector 320 is a conventional connector that lacks a thermal sensing module.

In some examples, each packet of temperature data 318, 328, 338, 339 transmitted by the thermal sensing modules 312, 322, 332, 333 is associated with an identifier of the thermal sensing module that generated the temperature data and/or the connector in which the temperature data was collected. In some examples, each packet may also be associated with a connector type (e.g., power receiving device, power supplying device, power cable. In some implementations, the connection monitoring module 350 is configured to discover the identities of the various connectors when the system is initialized. For example, the power receiving device 302 may report its identifier and may also report that it is mated with an identifier corresponding to connector 330. Likewise, the power supplying device 304 may report its identifier and may also report that it is mated with an identifier corresponding to connector 331. As such, the connection monitoring module 350 can identify mated connector pairs. Thus, when the temperature data 318, 328, 338, 339 is received by the connection monitoring module 350, the connection monitoring module 350 may distinguish among the temperature data and associate the temperature data with the corresponding connector.

In some examples, the connection monitoring module 350 continuously receives temperature data 318, 328, 338, 339 collected in connectors 310, 320, 330, 331 and generates a log of temperature data. The log may include entries that indicate a temperature reading, a connector associated with the temperature reading, a device associated with the connector, and a timestamp. As will be described in more detail below, the connection monitoring module 350 uses the temperature data 318, 328, 338, 339 to determine whether the power receiving device 302 is correctly or incorrectly connected to the power supplying device 304 and further uses the temperature data 318, 328, 338, 339 to detect a failure in the connection.

For further explanation, FIG. 3B sets forth a block diagram of another example power connection 301 for improving reliability, availability, and safety in a system using in-connector thermal monitoring in accordance with at least one embodiment of the present disclosure. The power connection 301 of FIG. 3B is similar to the power connection 300 of FIG. 3A except that the connector 330 of the power cable 306 is not configured with a thermal sensing unit. Instead, the data line 340 of the power cable 306 splits from the power cord and interfaces directly with the data port 316 of the connector 310. Thus, the connector 310 is able to receive the temperature data 339 generated by the connector 331 of the power cable 306.

For further explanation, FIG. 3C sets forth a block diagram of another example power connection 303 for improving reliability, availability, and safety in a system using in-connector thermal monitoring in accordance with at least one embodiment of the present disclosure. The power connection 303 of FIG. 3C is similar to the power connection 300 of FIG. 3A except that a conventional power cable 366 is used. Thus, in this example only the connector 310 of the power receiving device 302 and the connector 320 of the power supplying device 304 report temperature data 318, 328. In this example, the connection monitoring module 350 can still use only temperature data 318, 328 from the power receiving device 302 and power supplying device 304 to determine whether the power receiving device 302 is correctly or incorrectly connected to the power supplying device 304 and can further use the temperature data 318, 328 to detect a failure in the connection, as will be described in more detail below.

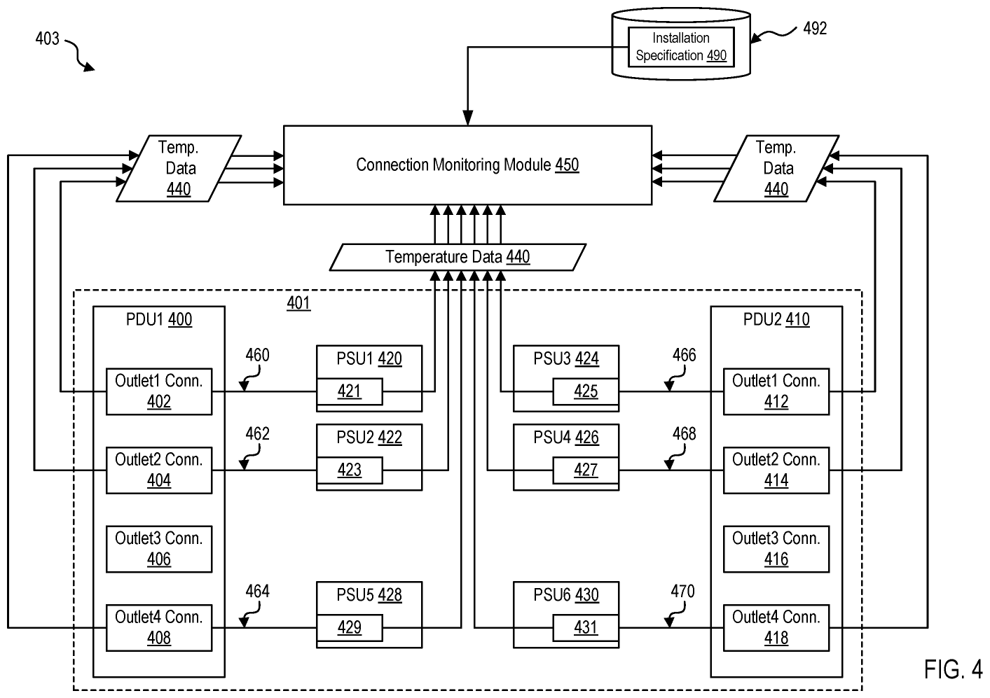

For further explanation, FIG. 4 sets forth a block diagram of another example installation 401 of power connections in a system 403 consistent with improving reliability, availability, and safety in a system using in-connector thermal monitoring in accordance with at least one embodiment of the present disclosure. The system 403 may be, for example, a rack unit that includes various devices such as servers, routers, and so on. The installation of FIG. 4 represents the expected installation, or correct installation, of power connections as defined in installation instructions, a specification, a manufacturer manual, or the like. The system 403 includes redundant PDUs: PDU1 400 and PDU2 410. PDU1 400 includes, in this example, four outlets, although a PDU may have any number of outlets. The four outlets correspond four connectors (e.g., receptacles): outlet1 connector 402, outlet2 connector 404, outlet3 connector 406, and outlet4 connector 408. Likewise, PDU2 410 includes, in this example, four outlets, although a PDU may have any number of outlets. The four outlets correspond four connectors (e.g., receptacles): outlet1 connector 412, outlet2 connector 414, outlet3 connector 416, and outlet4 connector 418.

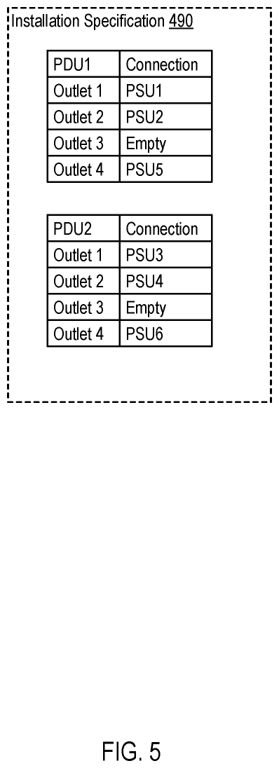

In this example, PDU1 400 and PDU2 distribute power to power supplies in the system 403. The power supplies include: PSU1 420, PSU2 422, PSU3 424, PSU4 426, PSU5, 428, and PSU6 430. The power supplies receive power from one of the PDUs and supply power to various devices in the system. Thus, in this arrangement, the PDUs correspond to power supplying devices discussed above and the PSUs correspond to power receiving device discussed above (although the PSUs are also power supplying devices through different connections not illustrated or discussed as they are not relevant to the present disclosure). In the example installation 401, with reference to PDU1 400, outlet1 connector 402 supplies power to connector 421 of PSU1 420 through power cable 460; outlet2 connector 404 supplies power to connector 423 of PSU2 422 through power cable 462; outlet4 connector 408 supplies power to connector 429 of PSU5 428 through power cable 464, and outlet3 connector 406 is empty. With reference to PDU2 410, outlet1 connector 412 supplies power to connector 425 of PSU3 424 through power cable 466; outlet2 connector 414 supplies power to connector 427 of PSU4 426 through power cable 468; outlet4 connector 418 supplies power to connector 431 of PSU6 430 through power cable 470, and outlet3 connector 416 is empty. These power connections may be detailed in an installation specification 490 that is stored in a storage device 492. For example, the installation specification 490 may be a data structure such as table. The installation specification 490 describes the expected installation, or correct installation, of power connections in system 403. For further explanation, FIG. 5 sets forth an example of the installation specification 490, in accordance with the present disclosure, that describes the installation of power connections consistent with the installation 401 of FIG. 4.

Returning to FIG. 4, connection monitoring module 450 is configured to receive temperature data 440 from PDU1 400 and PDU2 410 that includes temperature readings taken in any or all the connectors 402, 404, 408, 412, 414, 418, 421, 423, 425, 427, 429, 431 (and connectors 406, 416 if they were not empty). In some examples, cables 460, 462, 464, 466, 468, 470 are enhanced power cables, as discussed above, and thus PDU1 400, PDU2 410, PSU1 420, PSU2 422, PSU3 424, PSU4 426, PSU5 428, and/or PSU6 430 also report temperature data of the connectors (not shown for clarity) of the enhanced power cables.

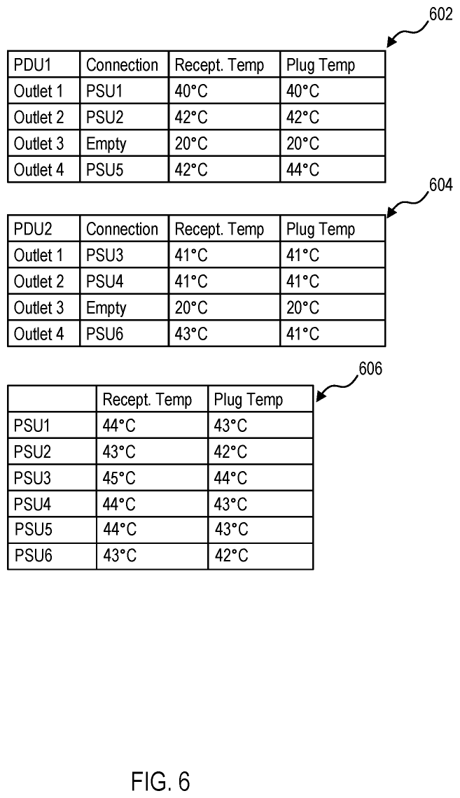

The connection monitoring module 450 is further configured to generate temperature logs. For further explanation, FIG. 6 sets forth example temperature logs 602, 604, 606 for improving reliability, availability, and safety in a system using in-connector thermal monitoring in accordance with at least one embodiment of the present disclosure. In the example of FIG. 6, temperature log 602 illustrates example temperature data reported by the connectors in PDU1 400, temperature log 604 illustrates example temperature data reported by the connectors in PDU2 410, and temperature log 606 illustrates example temperature data reported by the connectors of the PSUs. The temperature logs 602, 604, 606 represent expected temperatures that are consistent with a proper installation and normal operating conditions of the connectors. It should be noted that, in some examples, an ambient environmental temperature may have a particular expected value or expected range of values, and for purposes of illustration only an expected value of the ambient environmental temperature is assumed to be 20° C. in this disclosure; however, it should be appreciated that an ambient environmental temperature may have any expected value. In other examples, the connection monitoring module 450 may receive an actual ambient environmental temperature from a temperature sensor independent of the connectors. Thus, when an outlet is empty it is expected that the temperature reported by the connector will be approximately equal to the ambient environmental temperature. When two connectors are mated and current is flowing through them, it is expected that the temperature reported by the connectors will be higher than the ambient environmental temperature (e.g., approximately 20-25° higher than the ambient environmental temperature).

Returning to FIG. 4, connection monitoring module 450 is configured to identify and classify temperature abnormalities. In one example, a temperature abnormality may be based on an inconsistency with the installation specification. Such abnormalities may be detected during system initialization and continuously monitored to identify an incorrect installation of power connections. For example, a temperature in a connector may indicate that an outlet is mated with a power cable connector when that outlet is supposed to be empty. When the installation specification indicates that a PDU outlet is supposed to be empty, it is expected that the connector for that outlet will report an ambient environmental temperature. If the connector for that outlet reports a temperature higher than an ambient environmental temperature, such as a temperature consistent with a mated connection through which current is flowing, that temperature abnormality indicates an improper power connection. That is, a power cable is plugged into an outlet that is supposed to be empty. Conversely, if an outlet is supposed to be connected to a power cable but reports an ambient environmental temperature instead of a temperature indicative of current flow, then that temperature abnormality indicates that an outlet is empty when it is supposed to be connected to a PSU.

In another example, a temperature abnormality may be an overheating connector. To identify an overheating connector, the connection monitoring module 450 can, for example, compare the temperature reported by the connector to an absolute threshold or to a delta threshold of ambient environmental temperature to connector temperature. The connection monitoring module 450 can also compare the connector temperature to a range of expected operating temperatures when current is flowing through the connector. The connection monitoring module 450 can also compare the connector temperature to temperatures reported by other connectors to determine whether the temperature of that connector is consistent with other temperatures. The connection monitoring module 450 can also compare the temperatures of two mated connectors. In one example case, an overheating connector at one end of a connection and a normal temperature connector at the other end of the connection may indicate that overheating connector is either faulty or improperly connected (e.g., not fully plugged in). In another case, an overheating connector at both ends of the connection may indicate that the gauge of the power cord is too small or that the length of the power cord is excessively long, which could cause more current to flow thus resulting in overheating.

Various failure modes can be detected based on temperature data that indicates a connector is overheated. In the case of failing connector contacts, failing contacts will dissipate greater heating due to increasing resistance. The thermal sensors will be able to detect this increase of temperature over time by seeing an unexpected gradual increase in temperature or a sudden increase in temperature. In the case of a partially installed connector, the partially installed connector may result in poor or intermittent contact, resulting in excessive heating due to high electrical resistance or contact arcing. In the case of an incorrect wire gauge, a wire of insufficient wire gauge for the connected load will exhibit unexpectedly high electrical resistance which will result in excessive or unexpectedly high operating temperatures at the connector interface. In the case of excessive power cable length, a cable with grossly excessive length will have an overall high electrical resistance, reducing voltage at the load end. This can result in increased current consumption by the connected equipment, resulting in connector heating due to excessive current. In the case of an excessive load condition, an overloaded connection will exhibit unexpected heating at the connector interface. Early detection from temperature rise can allow for a proper investigation prior to the tripping of a protection device.

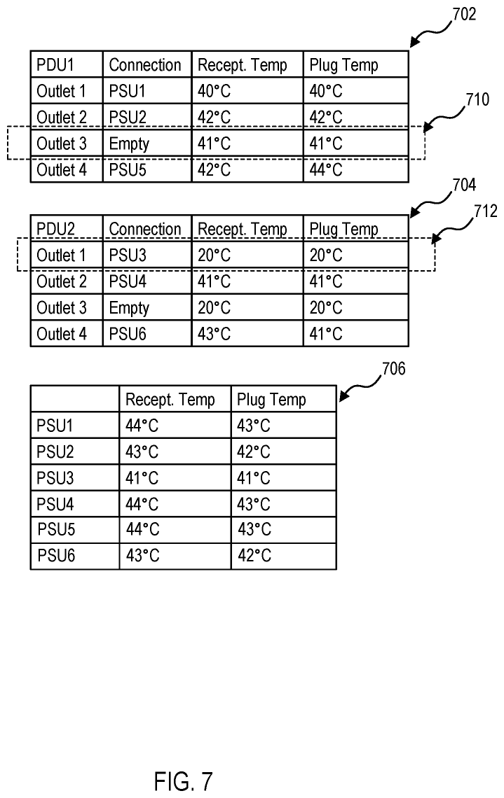

For further explanation, FIG. 7 sets forth additional example temperature logs 702, 704, 706 for improving reliability, availability, and safety in a system using in-connector thermal monitoring in accordance with at least one embodiment of the present disclosure. The example of FIG. 7 is similar to the example of FIG. 6. However, in the example of FIG. 7 temperature abnormalities are present. Like FIG. 6, the example of FIG. 7 includes a temperature log 702 that illustrates example temperature data reported by the connectors in PDU1 400, a temperature log 704 that illustrates example temperature data reported by the connectors in PDU2 410, and a temperature log 706 that illustrates example temperature data reported by the connectors of the PSUs. In the example of FIG. 7, the temperature log 702 of PDU1 400 indicates an abnormality 710 in that a higher-than-ambient environmental temperature is detected at outlet3, which should be empty according to the installation specification 490. The temperature at outlet3, which is similar to other mated connector pairs, indicates that current is flowing through the connectors at outlet3. The temperature log 704 of PDU2 indicates an abnormality 712 that an ambient environmental temperature is detected at outlet1 of PDU2, indicating that the outlet is empty, when outlet1 of PDU2 should be connected to PSU3 as indicated in the installation specification 490. The temperature log 706 of PSU temperature data indicates that all PSUs are connected. Thus, the connection monitoring module 450 can determine, based on the temperature data 480 and the installation specification 490, that the power connections in the system 403 are incorrectly installed. In this case, the connection monitoring module 450 can further determine that PSU3 is incorrectly connected to outlet3 of PDU1 400.

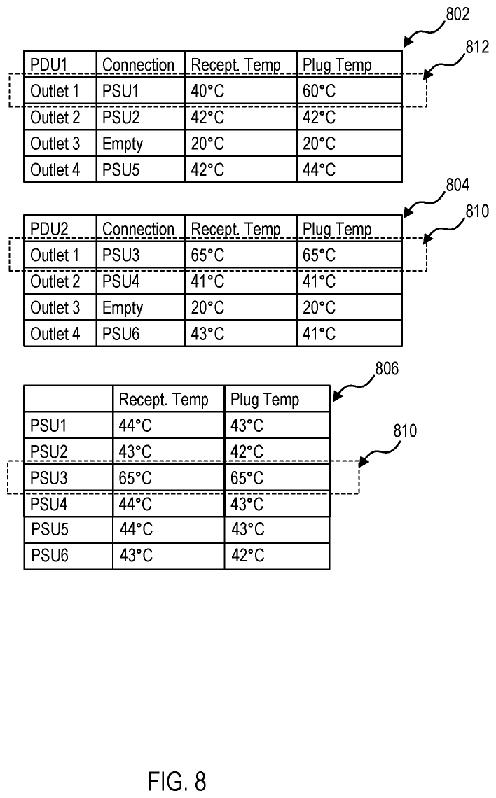

For further explanation, FIG. 8 sets forth additional example temperature logs 802, 804, 806 for improving reliability, availability, and safety in a system using in-connector thermal monitoring in accordance with at least one embodiment of the present disclosure. The example of FIG. 8 is similar to the example of FIG. 6. However, in the example of FIG. 8 temperature abnormalities are present. Like FIG. 6, the example of FIG. 8 includes a temperature log 802 that illustrates example temperature data reported by the connectors in PDU1 400, a temperature log 804 that illustrates example temperature data reported by the connectors in PDU2 410, and a temperature log 806 that illustrates example temperature data reported by the connectors of the PSUs. In the example of FIG. 8, the temperature log 804 of PDU2 410 and the temperature log 806 of the PSUs indicates an abnormality 810 in that abnormally high temperatures are detected at both ends of the power connection between outlet1 of PDU2 410 and PSU3 424. The abnormally high temperatures can be detected based on a range of expected temperatures, a comparison to an absolute temperature threshold, a comparison of difference between a reported temperature and the environmental temperature to a difference threshold, or a comparison of the reported temperatures to other reported temperatures. In this case, abnormally high temperatures at both ends of the connection may indicate, for example, an incorrect wire gauge, an excessive cable length, an overloaded connection, and similar conditions.

In the example of FIG. 8, the temperature log 802 of PDU1 400 indicates an abnormality 812 in that a temperature mismatch is detected between the connector (receptacle) of outlet1 of PDU1 400 and the connector (plug) of the power cable. The temperature mismatch may indicate, for example, that the connector of the cable is partially installed in the connector of outlet1 of PDU1 400, or that the contacts in the cable's connector are failing.

The example logs of FIGS. 6-8 are provided for illustrative and explanatory purposes and should not be construed as limitations on the present disclosure. It will be appreciated that the structure and content of the logs may vary while adhering to the spirit of the present disclosure. Further, the types of fault conditions that can be detected based on the connector temperature data, and/or the manner of detecting the fault conditions, may depart from the examples provided above while adhering to the spirit of the present disclosure.

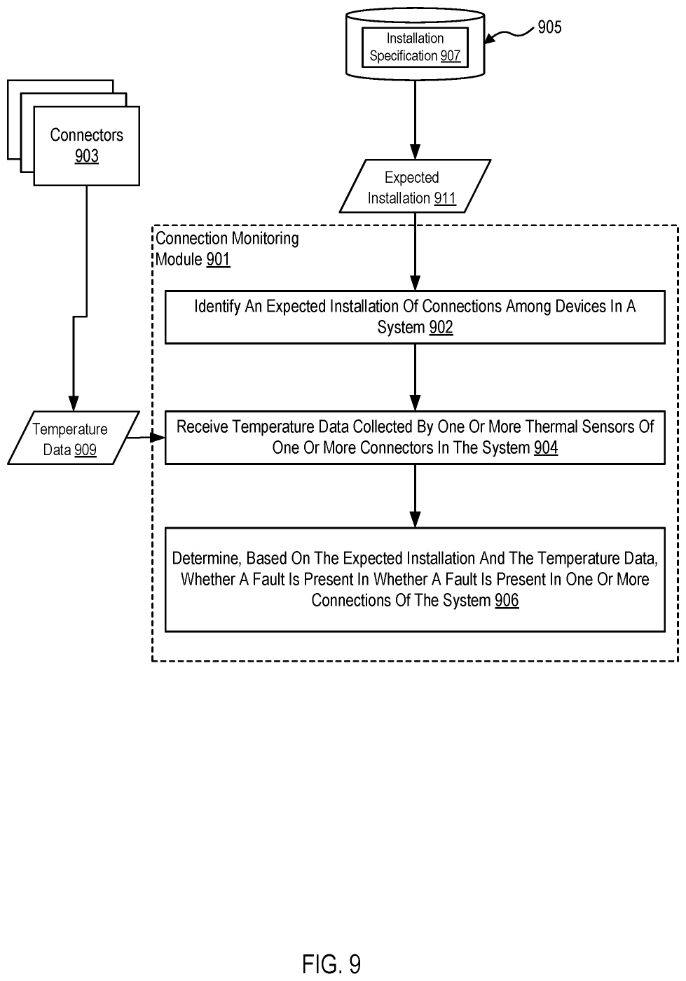

For further explanation, FIG. 9 sets forth a flow chart of an example method of improving reliability, availability, and safety in a system using in-connector thermal monitoring in accordance with at least one embodiment of the present disclosure. The method of FIG. 9 includes a connection monitoring module 901, which may be similar in features, functionality, and operation to the connection monitoring module 450 described above. In some examples, the connection monitoring module 901 is implemented by one or more microcontrollers, application specific integrated circuits (ASICs), field programmable gate arrays (FPGAs), or other hardware. In some examples, the connection monitoring module 901 is implemented by an application, such as one or more modules of computer program instructions that are stored in memory and executable by a processor. The connection monitoring module 901 may be integrated into one of the power distribution components of the system (e.g., a PDU) or may be independent of such components.

The example of FIG. 9 also includes one or more power connectors 903, which may be any of the types of connectors discussed above (e.g., power receiving device connectors, power supplying device connectors, PDU connectors, PSU connectors, power cable connectors, receptacles, plugs, etc.). The connectors 903 include a thermal sensing module that is coupled to or embedded within the connector 903 and that generates temperature readings of temperature within the connector 903. The example of FIG. 9 also includes a storage device 905 that stores an installation specification 907. The installation specification 907 describes the correct power connections between devices in a system. For example, the installation specification 907 may include a lookup table or other data structure that maps a power connection between a particular connector of a first device to a particular connector of a second device. For example, the installation specification 907 may be similar to the installation specification 490 shown in FIG. 5.

The method of FIG. 9 includes identifying 902 an expected installation 911 of connections among a plurality of devices in a system. In some examples, the connection monitoring module 901 identifies 902 the expected installation of power connections by accessing the installation specification 907 stored in storage device 905. In an illustrative example, the system may be a power distribution system of, for example, a rack unit that includes equipment such as servers, routers, and the like. In such an example, the power distribution system includes power distribution units and power supply units. The installation specification 907 maps, for example, a particular outlet of the PDU to a particular PSU for a particular power connection.

The method of FIG. 9 also includes receiving 904 temperature data 909 collected by one or more thermal sensors of one or more connectors in the system. In some examples, the connection monitoring module 901 receives the temperature data 909 through one or more communication paths between the connection monitoring module 901 and the connectors 903. For example, the connection monitoring module 901 may be communicatively coupled to the connectors 903 by one or more hard signal lines or by a wireless communications channel. The temperature data 909 may include temperature data from both mated and non-mated connectors. Thus, temperature data is reported by “empty” connectors as well as connectors that are actively transferring current. In some implementations, the temperature data 909 includes temperature readings from all connectors in the system that are equipped with thermal sensing capabilities. However, it is contemplated that as few as one connector per power connection is equipped with thermal sensing capabilities. Thus, temperature data relating to a particular power connection may be represented by a single thermal data point (e.g., temperature readings from only the PDU connector or only one PSU connector in the power connection). In a particular implementation, the temperature data 909 includes temperature readings from every thermal sensing PDU connector and every thermal sensing PSU connector in the system. In another particular implementation, the temperature data 909 includes temperature readings from every thermal sensing PDU connector, every thermal sensing PSU connector, and every thermal sensing cable connector in the system, regardless of whether a connector is mated with another connector. In some implementations, the temperature data is associated with an identifier corresponding to a connector in which the temperature readings were collected. The temperature data may be received through periodic transmission by the connector or in response to polling or other request made by the connection monitoring module 901.

Thus, in some examples, the temperature data 909 includes temperature data received at least from a thermal-sensing connector of a PDU. In some examples, the temperature data 909 includes temperature data received at least from a thermal-sensing connector of a PSU. In some examples, the temperature data 909 includes temperature data received at least from a thermal-sensing connector of a power cable. In a particular implementation, the temperature data 909 includes temperature data received from one or more thermal-sensing PDU connectors, one or more thermal-sensing PSU connectors, and one or more thermal-sensing power cable connectors.

The method of FIG. 9 also includes determining 906, based on the expected installation 911 and the temperature data 909, whether a fault is present in one or more connections of the system. In some examples, the connection monitoring module 901 determines 906 whether a fault is present by identifying whether the temperature data 909 and installation specification indicate a fault such as an incorrect power connection between devices, a partially installed connector, failing contacts in a connector, an incorrect gauge, an excessively length, or an excessive load condition. In some examples, the connection monitoring module 901 determines 906 whether a fault is present in the current connections among devices using the installation specification and a variety of temperature comparisons such as comparisons to ambient environmental temperature, comparisons of temperature data reported by different connectors, comparisons of temperature data to absolute or relative thresholds and ranges, and comparisons of temperature data to historical temperature data.

In a particular example, the connection monitoring module 901 uses the installation specification to identify which connectors should be reporting temperature data indicative of current flow and which connectors should be reporting a temperature indicative of ambient environmental temperature. For example, if the installation specification indicates an empty power connection, the corresponding connector should report temperature data indicative of ambient environment temperature. The ambient environmental temperature can be determined from data transmitted by a reference temperature sensor indicating the current ambient environment temperature, from a programmed reference temperature (e.g., a typical room temperature for the environment), or from an inference based on temperatures reported by other empty connectors).

Similarly, if the installation specification indicates a power connection to another device, the corresponding connector should report temperature data above the ambient environmental temperature, or more particularly, a temperature indicative of current flow through the connector. In various examples, the temperature indicative of current flow can be determined based on a reference temperature ranges or thresholds, historical temperature data, a temperature rise above the ambient environmental temperature, statistical analysis of the temperature data 909, and so on.

When the temperature data 909 indicates a configuration of power connections that is consistent with the installation specification, the connection monitoring module 901 determines that the power connections among devices in the system are correctly installed. When the temperature data 909 indicates a configuration of power connections that is inconsistent with the installation specification, the connection monitoring module 901 determines that a fault is present in the power connections among devices in the system due to an incorrect configuration of power connections, as will be explained in more detail below.

Although the connections among the devices are correctly installed, the connection monitoring module 901 continues to monitor temperature data reported by the connectors 903 to detect faults, for example, indicated by an overheating connector. In a particular example, the connection monitoring module 901 compares the temperature data 909 to determine whether a particular connector is overheating. An overheating connector can be detected based on a comparison of the temperature reading to one or more of an absolute temperature threshold, a range of expected temperatures, a threshold deviation from an ambient environmental temperature, a threshold deviation from other temperature readings from other connectors, and a threshold deviation from historical temperature averages. An overheating connector may be indicative of a partially installed connector, failing contacts in a connector, an incorrect gauge, an excessively long cable, or an excessive load condition. Using the installation specification, the connection monitoring module 901 can distinguish between temperature readings of mated connectors or temperature readings of connectors at opposite ends of the connection, which can be used to further diagnosis the fault causing the overheating connector(s).

When the temperature data 909 indicates that the temperatures reported by connectors 903 are consistent with normal operating temperatures, the connection monitoring module 901 determines that there is no indication of a fault in the power connections among devices in the system. When the temperature data 909 indicates that temperatures reported by one or more connectors 903 are inconsistent with normal operating temperatures, the connection monitoring module 901 determines that a fault is present in the power connections among the devices, as will be explained in more detail below.

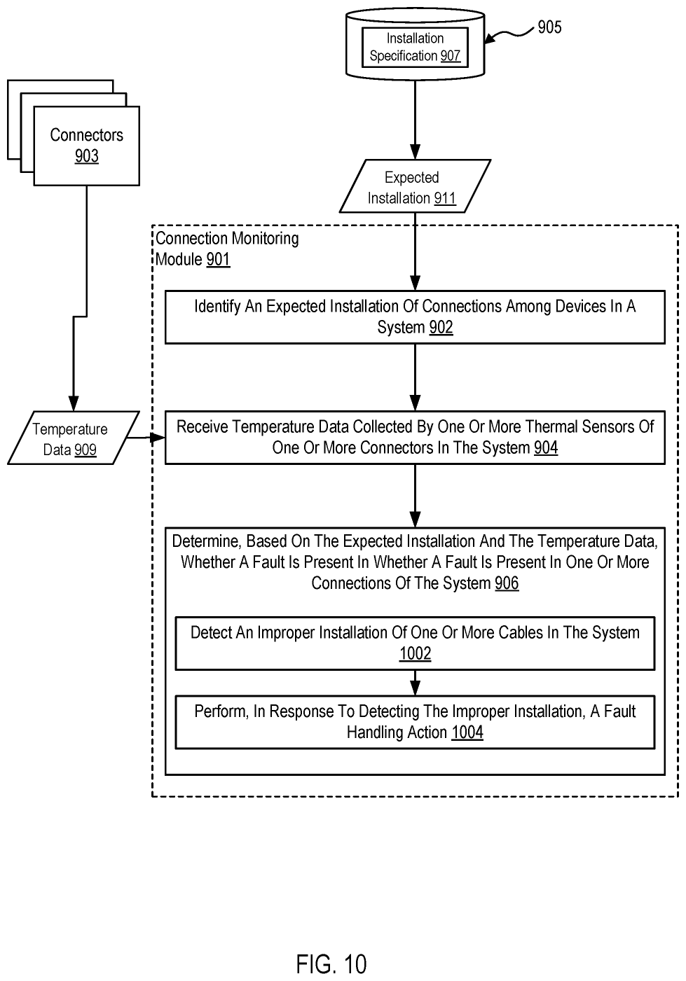

For further explanation, FIG. 10 sets forth a flow chart of an example method of improving reliability, availability, and safety in a system using in-connector thermal monitoring in accordance with at least one embodiment of the present disclosure. The method of FIG. 10 extends the method of FIG. 9 in that determining 906, based on the expected installation 911 and the temperature data 909, whether a fault is present in one or more connections of the system includes detecting 1002 an improper installation of one or more cables in the system. In some examples, the connection monitoring module 901 detects an improper installation of one or more power cables in the system by determining whether a temperature data from a particular connector indicates an empty connection or an active connection (through which current is flowing) and correlates the determination to the installation specification. For example, if the installation specification indicates that a connector (e.g., a PDU outlet) should be empty, the connection monitoring module 901 may detect an improper power cable installation when the temperature reading from that connector is above (e.g., by a threshold amount) the ambient environmental temperature, thus indicating heating due to current flow. If the installation specification indicates that a connector should be active and connected to another device, the connection monitoring module 901 may detect an improper power cable installation when the temperature reading from that connector is within a range of the ambient environmental temperature, thus indicating no heating due and therefore an absence of current flow.

The method of FIG. 10 also includes performing 1104, in response to detecting the improper installation, a fault handling action. In some examples, the connection monitoring module 901 performs 1004 a fault handling action that includes notifying a technician or a higher-level controller that an improper installation has been detected. In some implementations, the notification includes indicating which connector or connector location is the source of the error. Further, in some implementations the notification indicates a mismatch between two devices and/or how the error should be corrected (e.g., explaining that a PSU is connected to a first PDU outlet but should be connected to a second PDU outlet).

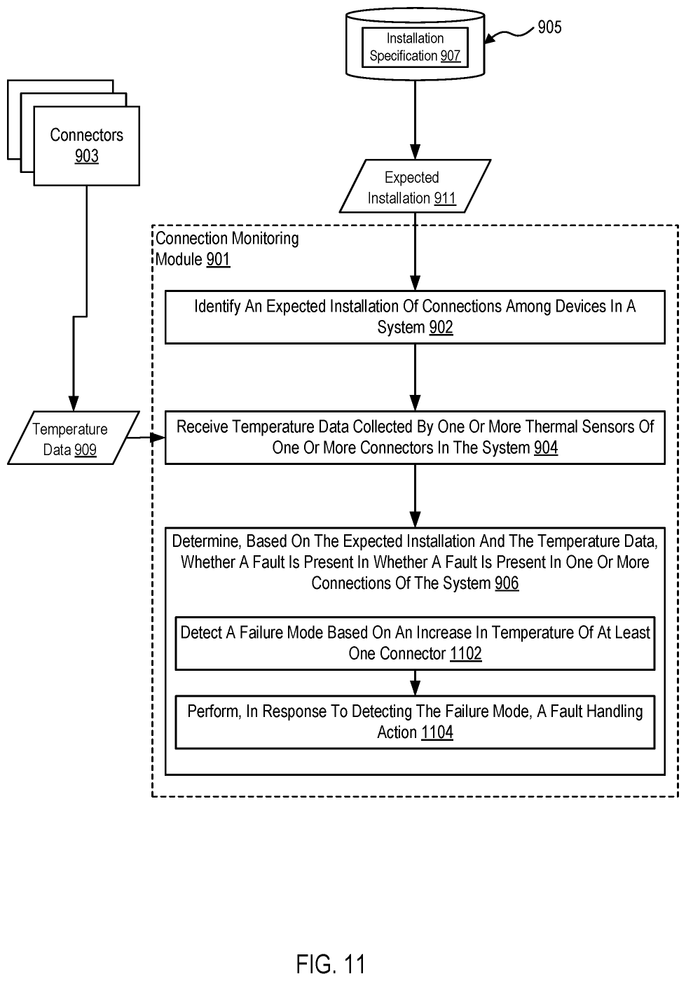

For further explanation, FIG. 11 sets forth a flow chart of an example method of improving reliability, availability, and safety in a system using in-connector thermal monitoring in accordance with at least one embodiment of the present disclosure. The method of FIG. 11 extends the method of FIG. 9 in that determining 906, based on the expected installation 911 and the temperature data 909, whether a fault is present in one or more connections of the system includes detecting 1102 a failure mode based on an increase in temperature of at least one connector. In some examples, the connection monitoring module 901 monitors the temperature data 909 to identify an increase in temperature experienced at a connector. As discussed above, an increase in temperature is indicative of various failure modes. In the case of failing connector contacts, failing contacts will dissipate greater heating due to increasing resistance. The thermal sensors will be able to detect this increase of temperature over time by seeing an unexpected gradual increase in temperature or a sudden increase in temperature. In the case of a partially installed connector, the partially installed connector may result in poor or intermittent contact, resulting in excessive heating due to high electrical resistance or contact arcing. In the case of an incorrect wire gauge, a wire of insufficient wire gauge for the connected load will exhibit unexpectedly high electrical resistance which will result in excessive or unexpectedly high operating temperatures at the connector interface. In the case of excessive power cable length, a cable with grossly excessive length will have an overall high electrical resistance, reducing voltage at the load end. This can result in increased current consumption by the connected equipment, resulting in connector heating due to excessive current. In the case of an excessive load condition, an overloaded connection will exhibit unexpected heating at the connector interface. Early detection from temperature rise can allow for a proper investigation prior to the tripping of a protection device.

In some examples, the connection monitoring module 901 identifies a temperature increase indicative of a failure mode by comparing temperature data to thresholds or ranges that are predefined to determine excessive heating or overheating conditions. In some implementations, the temperature data is compensated for ambient environment temperature and fluctuations in the ambient environment temperature before applying the threshold. In some examples, the connection monitoring module 901 comparing individual temperature readings of different connectors to identify that a particular connector's temperature deviates above the other connectors, which also compensates for ambient environmental temperature and operating or load conditions. In some examples, the connection monitoring module 901 uses heating patterns over time to classify the increase in temperature as indicative of a particular failure mode.

The method of FIG. 11 also includes performing 1104, in response to detecting the failure mode, a fault handling action. In some examples, the fault handling action includes notifying a technician or a higher-level controller of the failure mode. In various examples, the fault handling action further includes one or more of automatically actuating shunt trip circuit breakers, automatically opening relays, automatically controlling equipment to shut down or otherwise reduce load on the connection, and automatically initiating a failover to a different power supply in a redundant system.

Although examples in this disclosure discuss temperature data as being generated by a connector or microcontroller within the connector, it will be appreciated that temperature readings generated within the connector can be collected by any microcontroller including microcontrollers outside of any particular connector. Such microcontrollers may then transmit temperature data encompassing, for example, temperature readings collected from multiple connectors. For example, a particular power receiving device or power supplying device can include a microcontroller that generates temperature data based on temperature readings collected from all of its connectors and any connectors mated therewith. Further, examples of the disclosure are provided in the context of power connections, power connectors, and power device. However, the disclosure is not limited to such examples. For example, the connectors may be I/O connectors for I/O connections via I/O cables.

In view of the foregoing, it will be appreciated that improving reliability, availability, and safety in a system using in-connector thermal monitoring in accordance with the present disclosure improves the performance of computing equipment by mitigating damage and downtime due to the incorrect installation of power connections and faulty power connections though an analysis of temperature data reported by individual power connectors in a system.

Advantages of the described embodiments include:
Providing temperature data from a variety of different power connectors in a variety of system components that can be analyzed to locate points of failure in a system;
Rapidly and automatically detecting power cable mis-plugging, thus shortening the time to take corrective action; and
Rapidly and automatically detecting temperature rises that could be indicative of a failure mode in the connections, thus shortening the time to take corrective action.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
identifying an expected installation of connections among devices in a system;
receiving temperature data collected by one or more thermal sensors of one or more connectors in the system; and
determining, based on the expected installation and the temperature data, whether a fault is present in one or more connections of the system.

2. The method of claim 1, wherein the devices include one or more power supply devices and one or more power receive devices; and wherein the expected installation of power connections maps the one or more power supply devices to respective power connectors of the one or more power receive devices.

3. The method of claim 1, wherein each of the one or more connectors is at least one of a plug and a receptacle.

4. The method of claim 1, wherein the temperature data includes temperature readings from at least one power supply unit connector configured for thermal sensing.

5. The method of claim 1, wherein the temperature data includes temperature readings from at least one power distribution unit connector configured for thermal sensing.

6. The method of claim 1, wherein the temperature data includes temperature readings from at least one power cable connector configured for thermal sensing.

7. The method of claim 1, wherein the temperature data includes temperature readings from at least one power supply unit connector, at least one power cable connector, and at least one power distribution unit connector.

8. The method of claim 1, wherein a first connector is communicatively coupled to a connection monitoring module; wherein the first connector is mated with a second connector; and wherein the first connector receives temperature readings from the second connector.

9. The method of claim 1, wherein determining, based on the expected installation and the temperature data, whether a fault is present in one or more connections of the system includes:
detecting an improper installation of one or more cables in the system; and
performing, in response to detecting the improper installation, a fault handling action.

10. The method of claim 1, wherein determining, based on the expected installation and the temperature data, whether a fault is present in one or more connections of the system includes:
detecting a failure mode based on an increase in temperature at least one connector; and
performing, in response to detecting the failure mode, a fault handling action.

11. An apparatus comprising:
a processing device; and
memory operatively coupled to the processing device, wherein the memory stores computer program instructions that, when executed, cause the processing device to:
identify an expected installation of connections among devices in a system;
receive temperature data collected by one or more thermal sensors of one or more connectors in the system; and
determine, based on the expected installation and the temperature data, whether a fault is present in one or more connections of the system.

12. The apparatus of claim 11, wherein the devices include one or more power supply devices and one or more power receive devices; and wherein the expected installation of power connections maps the one or more power supply devices to respective power connectors of the one or more power receive devices.

13. The apparatus of claim 11, wherein the temperature data includes temperature readings from at least one power supply unit connector configured for thermal sensing.

14. The apparatus of claim 11, wherein the temperature data includes temperature readings from at least one power distribution unit connector configured for thermal sensing.

15. The apparatus of claim 11, wherein the temperature data includes temperature readings from at least one power cable connector configured for thermal sensing.

16. The apparatus of claim 11, wherein the temperature data includes temperature readings from at least one power supply unit connector, at least one power cable connector, and at least one power distribution unit connector.

17. The apparatus of claim 11, wherein a first connector is communicatively coupled to a connection monitoring module; wherein the first connector is mated with a second connector; and wherein the first connector receives temperature readings from the second connector.

18. The apparatus of claim 11, wherein determining, based on the expected installation and the temperature data, whether a fault is present in one or more connections of the system includes:
detecting an improper installation of one or more cables in the system; and
performing, in response to detecting the improper installation, a fault handling action.

19. The apparatus of claim 11, wherein determining, based on the expected installation and the temperature data, whether a fault is present in one or more connections of the system includes:
detecting a failure mode based on an increase in temperature at least one connector; and
performing, in response to detecting the failure mode, a fault handling action.

20. A computer program product comprising a computer readable storage medium, wherein the computer readable storage medium comprises computer program instructions that, when executed:
identify an expected installation of connections among devices in a system;
receive temperature data collected by one or more thermal sensors of one or more connectors in the system; and
determine, based on the expected installation and the temperature data, whether a fault is present in one or more connections of the system.
